(19) United States
(12) Patent Application Publication
(10) Pub. No.: US 2012/0187974 A1
(43) Pub. Date: Jul. 26, 2012

(54) Dual Stage Voltage Ramp Stress Test for Gate Dielectrics

(75) Inventors: David G. Brochu, JR., East Hardwick, VT (US); Roger A. Dufresne, Fairfax, VT (US); Charles B. LaRow, Burlington, VT (US); Travis S. Merrill, Rutland, VT (US); Nilufa Rahim, Somerset, NJ (US); Ernest Y. Wu, Essex Junction, VT (US)

(73) Assignee: INTERNATIONAL BUSINESS MACHINES CORPORATION, Armonk, NY (US)

(21) Appl. No.: 13/010,081

(22) Filed: Jan. 20, 2011

(51) Int. Cl. G01R 31/26

(52) U.S. Cl. 324/762.01

(57) ABSTRACT

A testing system for testing the integrity of a gate dielectric includes a testing apparatus, the testing apparatus including a test probe configured to contact and provide a voltage across the gate dielectric and to measure a current passing through the gate dielectric. The testing system also includes a computing device coupled to the testing apparatus an causing the testing apparatus to apply a constant voltage as part of a first test to the gate dielectric through the test probe until a first predetermined current is measured passing through the gate dielectric and to apply an increasing voltage to the gate dielectric after the first predetermined current is measured.

### BACKGROUND

The present invention relates to testing of semiconductor devices, and more specifically, to testing the integrity of gate dielectrics.

A gate dielectric is a dielectric used between the gate and substrate of a field effect transistor (FET). In operation, a voltage is applied to the gate to enable or disable electron migration between the source and drain of the FET. To avoid dielectric breakdown and leakage by quantum tunneling the gate dielectric can have varying thicknesses depending on the voltages that are to be applied to them.

As with most devices, testing may be done on the FET(s) after production to ensure that they are being formed properly. Historically, gate dielectric integrity has been investigated in the time-domain using the so-called “constant-voltage-stress” (CVS) methodology. The CVS methodology, while effective in some respects has some drawbacks. For example, the CVS methodology is, in general, time-consuming.

### SUMMARY

According to one embodiment of the present invention, a testing system for testing the integrity of a gate dielectric is disclosed. The system of this embodiment includes a testing apparatus, the testing apparatus including a test probe configured to contact and provide a voltage across the gate dielectric and to measure a current passing through the gate dielectric. The system of this embodiment also includes a computing device coupled to the testing apparatus and causing the testing apparatus to apply a constant voltage as part of a first test to the gate dielectric through the test probe until a first predetermined current is measured passing through the gate dielectric and to apply an increasing voltage to the gate dielectric after the first predetermined current is measured.

According to another embodiment of the present invention, a method of testing the integrity of a gate dielectric is disclosed. The method of this embodiment includes: applying a constant voltage as part of a first test to the gate dielectric through a test probe until a first predetermined current is measured passing through the gate dielectric; and applying an increasing voltage to the gate dielectric after the first predetermined current is measured.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 shows a system according to one embodiment of the present invention;

FIG. 2 shows a computing system on which embodiments of the present invention may be performed; and

FIG. 3 is a flow diagram illustrating a method according to one embodiment of the present invention.

### DETAILED DESCRIPTION

It has been discovered that products such as static random access memories (SRAMs) fail to function when dielectric breakdown causes the gate dielectric leakage current to reach a critical level. The time it takes to reach such a critical level shall be referred to herein as the “time-to-fail.”

Embodiments of the present invention take advantage of the discovery that such a failure is actually the combination of two different phases. The first phase occurs when a percolation path across the dielectrics is formed. Stated differently, the first phase ends after the “first breakdown” occurs. In the second phase, referred herein as the “post breakdown phase,” leakage currents rise and eventually reach the critical level (referred to herein as I_{fail}). Thus, the time-to-fail is the sum of the time required to reach the first breakdown added to the time required in the post breakdown phase to reach the critical level.

It has also been discovered that the distribution of time-to-fail including post-break down effects is demonstrated to exhibit a non-Weibull distribution. As such, if only the CVS measurements are used, an extremely large size of samples for CVS measurements may be required. In addition, dielectric failure follows a bimodal behavior known as extrinsic mode in the earlier times and intrinsic mode at later times. In general, product reliability is dominated by extrinsic mode (also commonly referred to as extrinsic defects) in its useful lifetime. Due to the lack of an efficient methodology in the manufacturing environment, the reduction of extrinsic defect density is only achieved by an expensive product functional stress known as burn-in. In summary, an efficient and comprehensive methodology is lacking for the dielectric integrity evaluation of extrinsic and intrinsic modes including the post breakdown phase.

In addition to the aforementioned CVS methodology, gates can also be tested by a so-called voltage ramp stress (VRS) methodology. In the VRS methodology, the voltage on the gate is increased until the current through the gate (and thus, through the dielectric) changes. The voltage can be increased in many different manners including, but not limited to, in linear steps, exponential steps, or combinations thereof. The VRS methodology is much faster than the CVS methodology.

According to embodiments of the present invention, both methodologies are utilized. In particular, embodiments of the present invention are directed to utilizing a two-phase stress method that utilizes, in a first phase, CVS methods to first reach the first breakdown and utilizes, in a second phase (post breakdown phase), the VRS methods to reach I_{fail}.

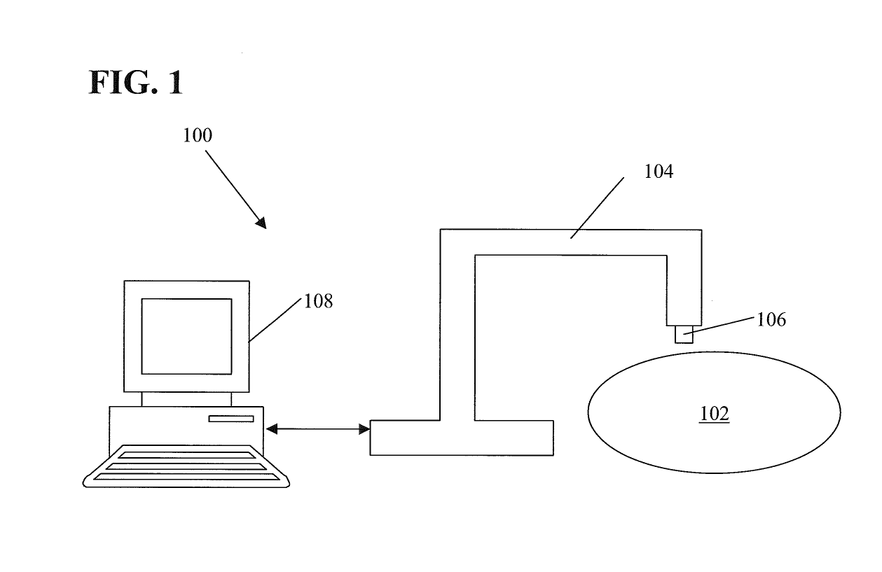

FIG. 1 illustrates a testing system 100 according to an embodiment of the present invention. In one embodiment, the testing system 100 performs oxide integrity tests on one or more gates on a wafer or other test substrate 102. To that end, the system can include a testing apparatus 104. The testing apparatus 104 could be located, for example, at any location in a semiconductor processing line or could be separate there from. The testing apparatus 104 may include a testing probe 106. The testing probe 106 can provide a voltage to, for example, a gate contact located on the test substrate 102. It shall be understood, that as well as being able to provide a voltage at the testing probe 106, the testing apparatus 104 may also be configured to measure a current passing through the testing probe 106. As such, the testing apparatus 104 can be utilized to perform the testing described above. In particular, in one embodiment, the testing apparatus 104 causes (or is commanded to cause) a constant stress voltage to be provided to the test probe 106 during a time period when the test probe 106 is brought into contact with a gate or gate contact on the test substrate. The constant stress voltage is applied until the current passing through the test probe 106 increases either above a threshold level or at a rate exceeding a predetermined level. Either condition can indicate that the first phase has been completed, e.g., that the first breakdown has occurred.

After the first break down has occurred, a voltage ramp stress is applied by the test probe 104 until I_{fail} is reached. In the event that the voltage can be raised above normal operating voltages and I_{fail} has not been reached, it may be determined that the test substrate (or at least the gate under test) has passed the particular test.

In FIG. 1, the test system 100 is illustrated as including a computing device 108. This computing device 108 can be part of the testing apparatus 104 in one embodiment or may be a separate element. Regardless, the computing device 108 can cause the testing apparatus 104 to perform the methods disclosed herein.

It shall be understood that the testing system 100 shown in FIG. 1 is merely illustrative and any type of now known or later developed testing system that can perform or be caused to perform the methods disclosed herein may be utilized without departing from embodiments of the present invention.

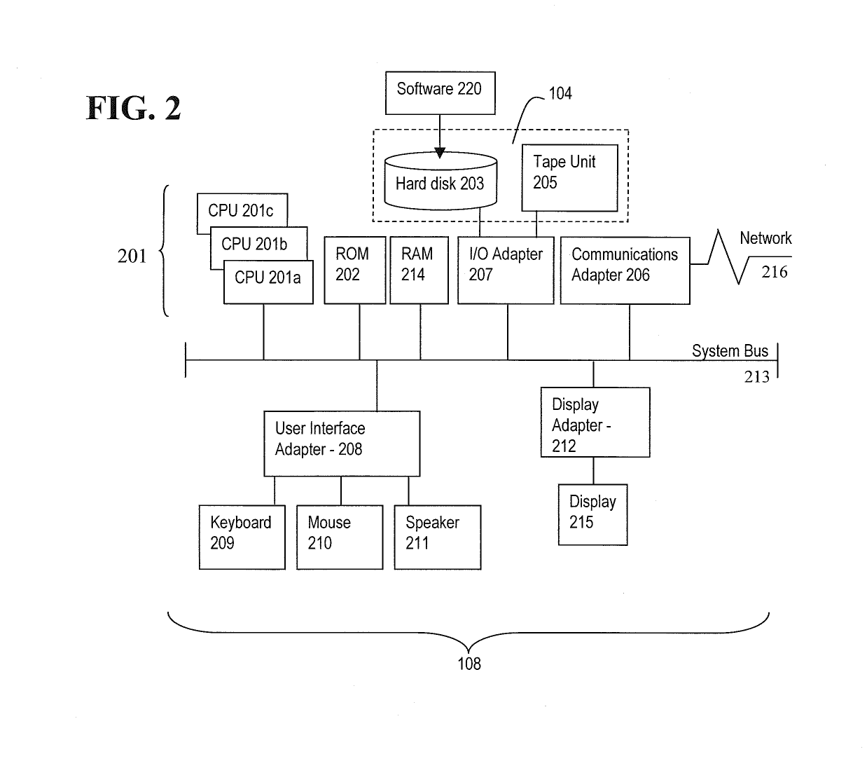

FIG. 2 shows an example of a computing system on which embodiments of the present invention may be implemented 200. The computing system 200 could be, for example, the computing device 108. In this embodiment, the system 200 has one or more central processing units (processors) 201a, 201b, 201c, etc. (collectively or generically referred to as processor(s) 201). In one embodiment, each processor 201 may include a reduced instruction set computer (RISC) microprocessor. Processors 201 are coupled to system memory 214 and various other components via a system bus 213. Read only memory (ROM) 202 is coupled to the system bus 213 and may include a basic input/output system (BIOS), which controls certain basic functions of system 200.

FIG. 2 further depicts an input/output (I/O) adapter 207 and a network adapter 206 coupled to the system bus 213. I/O adapter 207 may be a small computer system interface (SCSI) adapter that communicates with a hard disk 203 and/or tape storage drive 205 or any other similar component. I/O adapter 207, hard disk 203, and tape storage device 205 are collectively referred to herein as mass storage 204. A network adapter 206 interconnects bus 213 with an outside network 216 enabling computing system 200 to communicate with other such systems. A screen (e.g., a display monitor) 215 is connected to system bus 2113 by display adaptor 212, which may include a graphics adapter to improve the performance of graphics intensive applications and a video controller. In one embodiment, adapters 207, 206, and 212 may be connected to one or more I/O busses that are connected to system bus 213 via an intermediate bus bridge (not shown). Suitable I/O buses for connecting peripheral devices such as hard disk controllers, network adapters, and graphics adapters typically include common protocols, such as the Peripheral Components Interface (PCI). Additional input/output devices are shown as connected to system bus 213 via user interface adapter 208 and display adapter 212. A keyboard 209, mouse 210, and speaker 211 are all interconnected to bus 213 via user interface adapter 208, which may include, for example, a Super I/O chip integrating multiple device adapters into a single integrated circuit.

Thus, as configured in FIG. 2, the system 200 includes processing means in the form of processors 201, storage means including system memory 214 and mass storage 204, input means such as keyboard 209 and mouse 210, and output means including speaker 211 and display 215. In one embodiment, a portion of system memory 214 and mass storage 204 collectively store an operating system such as the AIX® operating system from IBM Corporation to coordinate the functions of the various components shown in FIG. 1.

It will be appreciated that the system 200 can be any suitable computer or computing platform, and may include a terminal, wireless device, information appliance, device, workstation, mini-computer, mainframe computer, personal digital assistant (PDA) or other computing device. It shall be understood that the system 100 may include multiple computing devices linked together by a communication network. For example, there may exist a client-server relationship between two systems and processing may be split between the two.

Users of the system 200 can connect to the network through any suitable network interface 216 connection, such as standard telephone lines, digital subscriber line, LAN or WAN links (e.g., T1, T3), broadband connections (Frame Relay, ATM), and wireless connections (e.g., 802.11(a), 802.11(b), 802.11(g)).

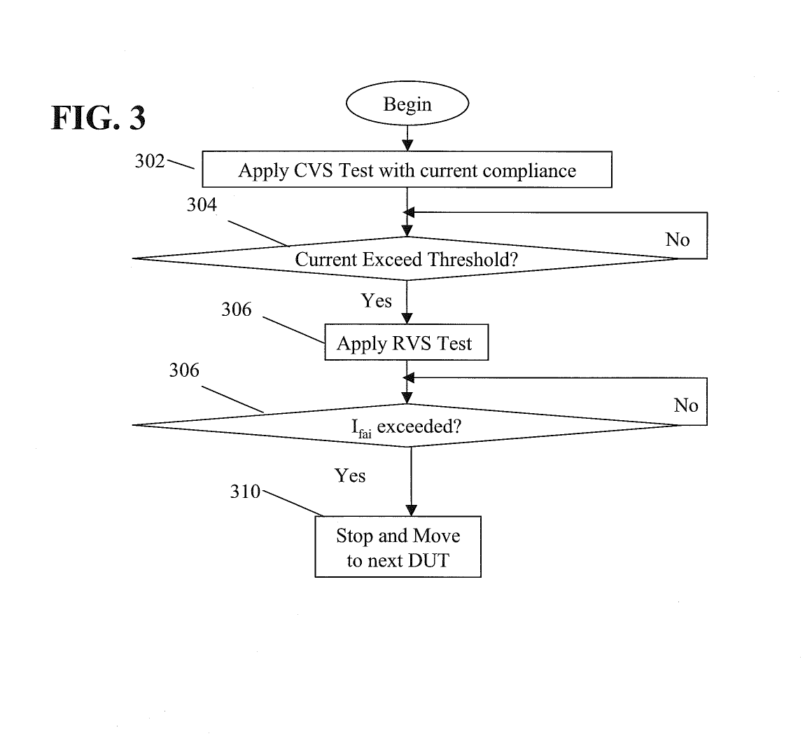

FIG. 3 illustrates a method according to an embodiment of the present invention. The method begins at process 302 where a CVS is applied to one or more gates or gate contacts of a test substrate. In one embodiment, a relatively high voltage is applied to the gate by a test probe for a short stress time. During this time the first break down occurs. The CVS is applied until the current through the gate increases by a specified amount or at a specified rate as illustrated by process 304. In one embodiment, the amount of increase is very low such that the breakdown is arrested before progressing into (or very far into) the post breakdown phase described above. After process 304, a VRS is applied to the gate or gate contact at process 306. The VRS is ramped up until I_{fail} is achieved as shown at process 308. The voltage level previous to or when I_{fail} was achieved may then be compared to standards to determine if the test was successful at process 310.

In one embodiment, the voltage level determined at process 308 corresponds to the voltage-to-fail in the post breakdown phase and can be converted to the residual times-to-fail for a given voltage acceleration model. Of course, the voltage acceleration factor of a given model can be determined by using a different ramp rate.

The capabilities of the present invention can be implemented in software, firmware, hardware or some combination thereof.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized to store instructions for execution of methods disclosed herein or to cause a computing device to perform the methods disclosed herein. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

Technical effects include providing methods for testing the integrity of one or more gate dielectrics on a test substrate.

The diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated. Moreover, the use of the terms first, second, etc. do not denote any order or importance, but rather the terms first, second, etc. are used to distinguish one element from another.

What is claimed is:

1. A testing system for testing the integrity of a gate dielectric, the system comprising:
a testing apparatus, the testing apparatus including a test probe configured to contact and provide a voltage across the gate dielectric and to measure a current passing through the gate dielectric; and
a computing device coupled to the testing apparatus and causing the testing apparatus to apply a constant voltage as part of a first test to the gate dielectric through the test probe until a first predetermined current is measured passing through the gate dielectric and to apply an increasing voltage to the gate dielectric after the first predetermined current is measured.

2. The testing system of claim 1, wherein the increasing voltage is applied until a second current is reached.

3. The testing system of claim 2, wherein the increasing voltage is increased in steps.

4. The testing system of claim 3, wherein the increasing voltage is increased by increased by linear steps.

5. The testing system of claim 3, wherein the increasing voltage is increased by exponentially increasing steps.

6. The testing system of claim 1, wherein the constant voltage is applied as part of a constant voltage stress test.

7. The testing system of claim 1, wherein the increasing voltage is applied as a part of a voltage ramp stress test.

8. A method of testing the integrity of a gate dielectric, the method comprising:
applying a constant voltage as part of a first test to the gate dielectric through a test probe until a first predetermined current is measured passing through the gate dielectric; and
applying an increasing voltage to the gate dielectric after the first predetermined current is measured.

9. The method of claim 8, wherein applying the increasing voltage includes increasing the voltage a second current is reached.

10. The method of claim 9, wherein the increasing voltage is increased in steps.

11. The method of claim 10, wherein the increasing voltage is increased by linear steps.

12. The method of claim 10, wherein the increasing voltage is increased by exponentially increasing steps.

13. The method of claim 8, wherein the constant voltage is applied as part of a constant voltage stress test.

14. The testing system of claim 8, wherein the increasing voltage is applied as a part of a voltage ramp stress test.
